(19) United States
(12) Patent Application Publication
(10) Pub. No.: US 2006/0240664 A1
(43) Pub. Date: Oct. 26, 2006

(54) Method of manufacturing multi-layered substrate

(76) Inventors: Kenji Wada, Fujimi (JP); Haruki Ito, Chino (JP); Hideo Imai, Shimosuwa (JP)

Correspondence Address: HARNESS, DICKEY & PIERCE, P.L.C., P.O. BOX 828, BLOOMFIELD HILLS, MI, 48303, US

(21) Appl. No.: 11/396,255

(22) Filed: Mar. 31, 2006

(30) Foreign Application Priority Data
Apr. 1, 2005 (JP) 2005-105765

(51) Int. Cl. H01L 21/4763

(52) U.S. Cl. 438/639; 438/622

(57) ABSTRACT

A method of manufacturing a multi-layered substrate includes providing an electronic component on a surface of a substrate so that a terminal of the electronic component faces upward. The method also includes providing a first insulation pattern on the surface so as to fill a step generated due to a thickness of the electronic component.

### FIELD

The present invention relates to a method of manufacturing a multi-layered substrate and, in particular, to a method of manufacturing a multi-layered substrate by an inkjet process.

### BACKGROUND

A method of manufacturing a wiring substrate or a circuit substrate by a printing method is used because the process can be performed at low cost compared to a method of manufacturing a wiring substrate or a circuit substrate by repeating a process of coating a thin film and a process of photolithography.

Although forming a conductive pattern by an inkjet method is known as a technique that uses an additive process (see for example, JP-A-2004-6578), a method of manufacturing a multi-layered substrate having an electronic component embedded therein by an inkjet process is not known in the related art.

### SUMMARY

An advantage of some aspects of the present teachings is that it provides a multi-layered substrate having an electronic component embedded therein by an inkjet process.

According to an aspect of the present teachings, there is provided a method of manufacturing a multi-layered substrate. The method includes steps of providing an electronic component on a surface so that a terminal of the electronic component faces upward, and providing a first insulation pattern on the surface so as to fill a step generated due to a thickness of the electronic component.

It is preferable that the method further includes steps of providing a second insulation pattern on the first insulation pattern to form a via hole on an edge of the terminal, and providing a conductive post in the via hole.

It is preferable that the method further includes steps of providing a conductive post on the terminal, and providing a second insulation pattern on the first insulation pattern so as to surround the sides of the conductive post.

It is preferable that the method further includes steps of providing a conductive pattern on the second insulation pattern to be connected to the conductive post, and providing a third insulation pattern on the second insulation pattern to eliminate a step generated due to a thickness of the conductive pattern.

It is preferable that the method further includes steps of providing a second insulation pattern on the first insulation pattern to form a via hole on an edge of the terminal, and forming a conductive pattern on the terminal and the second insulation pattern.

It is preferable that the method further includes providing a third insulation pattern on the second insulation pattern to fill a step generated due to a thickness of the conductive pattern.

According to another aspect of the present teachings, there is provided a method of manufacturing a multi-layered substrate, including steps of providing an electronic component on a surface so that a bump of the electronic component faces upward, providing a first insulation pattern on the surface to cover the electronic component except for the bump, providing a second insulation pattern on the first insulation pattern to surround the sides of the bump, and providing a conductive pattern on the second insulation pattern to be connected to the bump.

According to another aspect of the present teachings, there is provided a method of manufacturing a multi-layered substrate, including steps of providing an electronic component on a conductive pattern so that a terminal of the electronic component comes in contact with a surface of the conductive pattern, and providing an insulation pattern to fill at least a step generated due to a thickness of the electronic component.

According to another aspect of the present teachings, there is provided a method of manufacturing a multi-layered substrate including steps of providing a conductive pattern on a surface so that the conductive pattern contacts a terminal of an electronic component provided on the surface, and providing an insulation pattern on the surface to fill at least a step generated due to the thickness of the electronic component.

According to the present teachings, a step generated due to a thickness of the electronic component is filled. Accordingly, it is possible to form a layer covering, the electronic component by an inkjet process. Furthermore, it is possible to manufacture a multi-layered substrate having an electronic component embedded therein by an inkjet process.

### BRIEF DESCRIPTION OF THE DRAWINGS

The invention will be described with reference to the accompanying drawings, wherein like numbers reference like elements.

FIGS. 1A to 1D are views illustrating a manufacturing method according to an embodiment;

FIGS. 2A to 2D are views illustrating a manufacturing method according to an embodiment;

FIGS. 3A and 3B are views illustrating a manufacturing method according to an embodiment;

FIG. 4 is a cross-sectional view of a multi-layered substrate according to an embodiment;

FIGS. 5A to 5E are views illustrating a manufacturing method according to a first exemplary example;

FIGS. 6A to 6E are views illustrating a manufacturing method according to a first exemplary example;

FIGS. 7A to 7D are views illustrating a manufacturing method according to a first exemplary example;

FIGS. 8A and 8B are views illustrating a manufacturing method according to a first exemplary example;

FIGS. 9A to 9D are views illustrating a manufacturing method according to a second exemplary example;

FIGS. 10A and 10E are views illustrating a manufacturing method according to a third exemplary example;

FIGS. 11A to 11C are views illustrating a manufacturing method according to a third exemplary example;

FIGS. 12A to 12D are views illustrating a manufacturing method according to a fourth exemplary example;

FIGS. 13A and 13B are views illustrating a manufacturing method according to a fourth exemplary example;

FIGS. 14A to 14D are views illustrating a manufacturing method according to a fifth exemplary example;

FIGS. 15A and 15B are views illustrating a manufacturing method according to a fifth exemplary example;

FIG. 16 is a view illustrating a liquid droplet ejection apparatus used in manufacturing a multi-layered substrate;

FIGS. 17A and 17B are views illustrating a head in a liquid droplet ejection apparatus; and

FIG. 18 is a block diagram illustrating a controller in a liquid droplet ejection apparatus.

### DETAILED DESCRIPTION

An embodiment describes a method of manufacturing a multi-layered substrate 1 as shown in FIG. 4 by an inkjet process. A process of manufacturing the multi-layered substrate 1 will be first described. In addition, a method of manufacturing the multi-layered substrate 1 will be described in detail by placing priority to each of three sections 1A, 1B, and 1C.

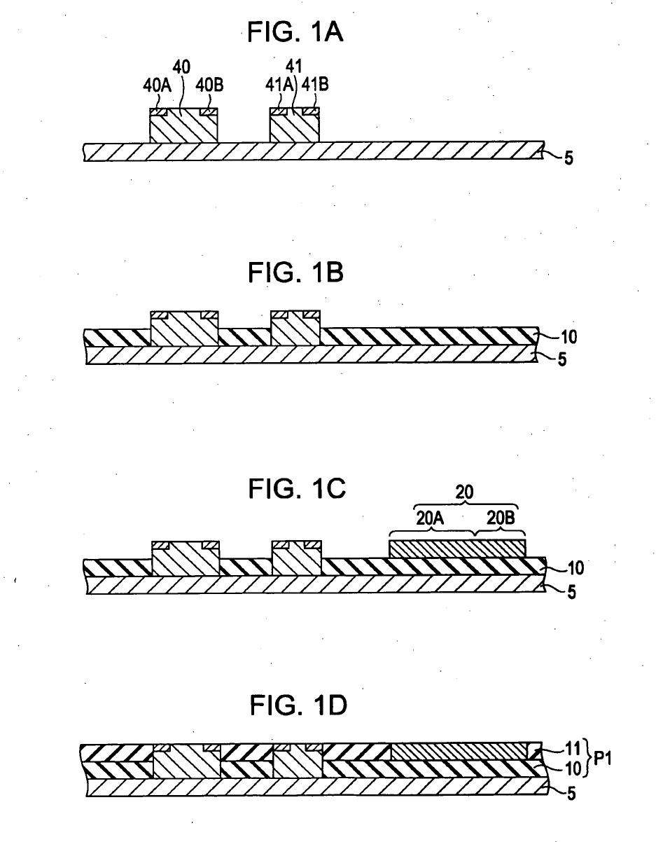

As shown in FIG. 1A, two electronic components 40 and 41 are provided on a surface of a base layer 5 using a mounter. The electronic component 40 is provided such that two terminals 40A and 40B of the electronic component 40 face upward. Similarly, the electronic component 41 is provided such that two terminals 41A and 41B of the electronic component 41 face upward. The base layer 5 is a flexible substrate made of polyimide, and is shaped like a tape.

In the present embodiment, the electronic components 40 and 41 have the same thickness. The electronic component 40 is a surface-mounted resistor. The electronic component 41 is a chip inductor. In another embodiment, the electronic components 40 and 41 may be rectangular chip resistors, rectangular chip thermistors, diodes, varistors, LSI bare chips, or LSI packages.

As shown in FIG. 1B, after providing the electronic components 40 and 41, an insulation sub-pattern 10 is formed by an inkjet sub-process on a portion of the base layer 5 where the electronic components 40 and 41 are not provided.

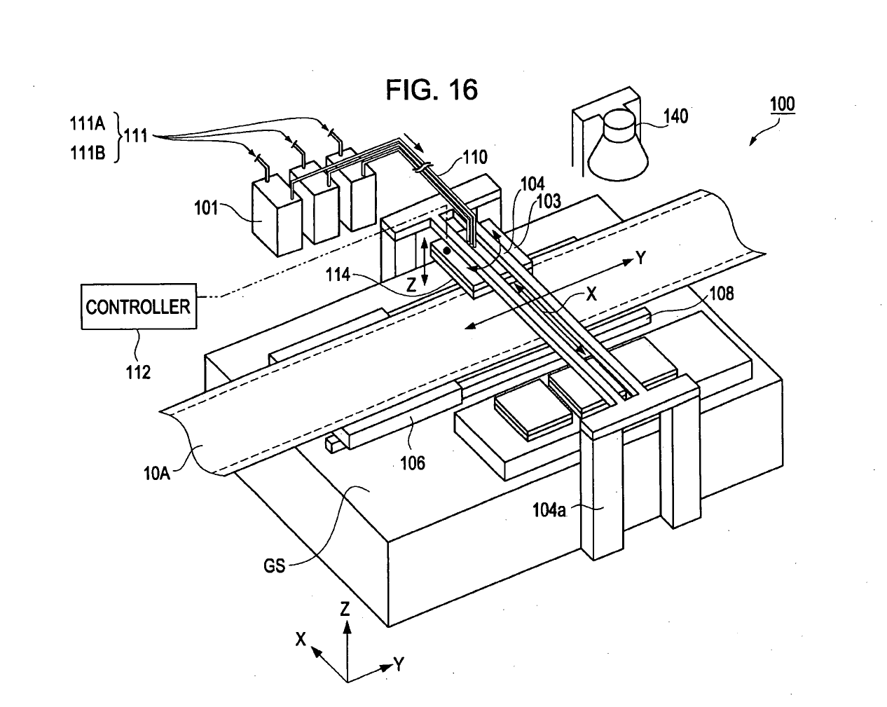

An ‘inkjet sub-process’ includes a process of forming a layer, film, or pattern on a surface of an object by using, for example, a liquid droplet ejection apparatus 100, which is described in FIG. 16. The liquid droplet ejection apparatus 100 is an apparatus for placing liquid droplets D1 of an insulation material 111A or liquid droplets D2 of a conductive material 111B on a predetermined position of a surface of an object. The liquid droplet D1 or liquid droplet D2 is ejected from a nozzle 118 of a head 114 in the liquid droplet ejection apparatus 100 according to ejection data applied to the inkjet droplet ejection apparatus 100. The insulation material 111A and the conductive material 111B are a type of an aqueous material 111.

The ‘inkjet sub-process’ may also include a process of making a surface lyophilic with respect to the insulation material 111A or conductive material 111B. In addition, the ‘inkjet sub-process’ may include a process of making a surface lyophobic with respect to the insulation material 111A or conductive material 111B.

In addition, the ‘inkjet sub-process’ may include a process of activating a layer, film, or pattern formed on a surface of an object. In a case using the insulation material 111A, the activation process includes a process of curing a resin material contained in the insulation material 111A and/or a process of vaporizing a solvent from the insulation material 111A. In a case using the conductive material 111B, the activation process is a process of welding or sintering conductive particles contained in the conductive material 111B. The activation process will be described in more detail below.

It should be understood that one or more ‘inkjet sub-processes’ may be collectively referred to as an ‘inkjet process’.

Returning to FIG. 1B, when the insulation sub-pattern 10 is formed by the inkjet sub-process, the total number of liquid droplets D1 ejected to the base layer 5, positions of the liquid droplets D1, and intervals between the positions of the liquid droplets D1 are adjusted so that the insulation sub-pattern 10 has a substantially flat surface and surrounds the sides of the electronic components. 40 and 41. In addition, in the present embodiment, in order to prevent a thickness of the insulation sub-pattern 10 from exceeding a thickness of the electronic components 40 and 41, the total number of ejected liquid droplets D1 or intervals between positions of the liquid droplets D1 is adjusted. As described in the sixth exemplary example, the above-mentioned adjustment is achieved by changing the ejection data provided in the liquid droplet ejection apparatus 100.

As a result, the upper surface of the insulation sub-pattern 10 is substantially flat. In the present embodiment, the upper surface of the insulation sub-pattern 10 is substantially flat with respect to a surface of the base layer 5. However, when the upper surface of the insulation sub-pattern 10 is substantially flat, the upper surface of the insulation sub-pattern 10 may be inclined with respect to the surface of the base layer 5. The expression of a ‘substantially flat’ surface implies a surface on which a pattern can be formed by the inkjet sub-process, or a surface on which an electronic component can be provided.

Next, as shown in FIG. 1C, a conductive pattern 20 is formed on part of the insulation sub-pattern 10 by the inkjet sub-process. In the present embodiment, the conductive pattern 20 has an electrode 20A and a conductive wire 20B connected to the electrode 20A. The electrode 20A becomes subsequently part of a capacitor. In addition, the surface of the conductive pattern 20 is substantially flat. In addition, in the present embodiment, the upper surface of the conductive pattern 20 is formed to be almost at the same level as the upper surface of the electronic components 40 and 41.

Next, as shown in FIG. 1D, the insulation sub-pattern 11 is formed on the insulation sub-pattern 10 by the inkjet sub-process. The insulation sub-pattern 11 is formed to surround a side of each of the electronic components 40 and 41, and sides of the conductive pattern 20. In the present embodiment, the insulation sub-pattern 11 and the conductive pattern 20 are almost equal in thickness to each other.

In addition, in the present embodiment, the sum of thicknesses of the insulation sub-patterns 10 and 11 is equal to a thickness of each of the electronic components 40 and 41. Accordingly, the stacked insulation sub-patterns 10 and 11 are used to fill a step generated due to the thickness of the electronic components 40 and 41. In addition, in the present embodiment, the upper surface of the insulation sub-pattern 11 is formed to be at the same level as the upper surface of each of the electronic components 40 and 41. In the present embodiment, the two insulation sub-patterns 10 and 11 are also referred to as an ‘insulation pattern P1’.

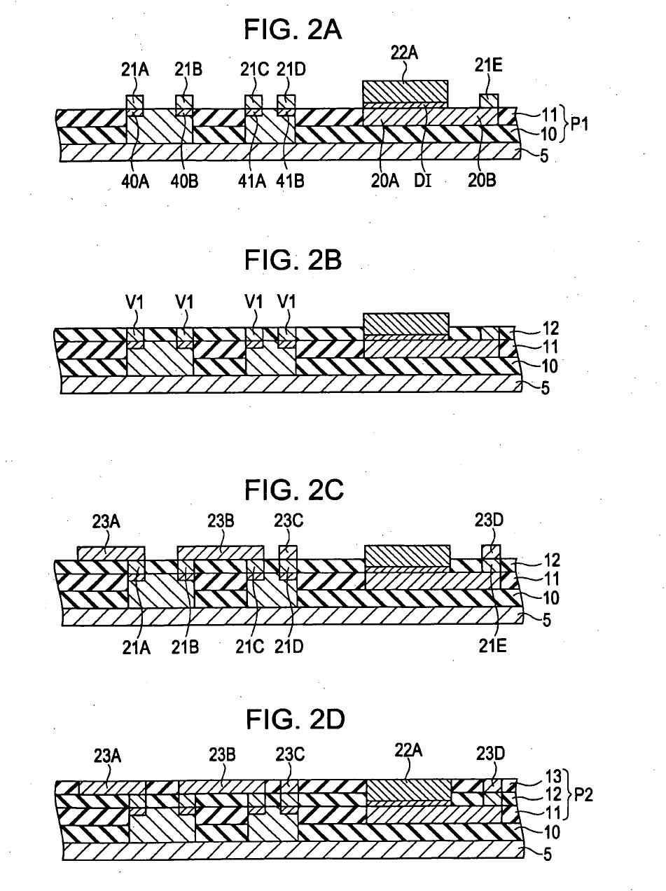

Next, as shown in FIG. 2A, a dielectric layer DI is formed on the electrode 20A by the inkjet sub-process. An electrode 22A serving as a conductive pattern is formed on the dielectric layer DI by the inkjet sub-process. The dielectric layer DI, electrode 22A, and electrode 20A form a capacitor 42 (i.e., an electronic component). In the inkjet sub-process, an aqueous material 111 for forming the dielectric layer DI is substantially equal to the insulation material 111A.

As shown in FIG. 2A, conductive posts 21A, 21B, 21C, 21D, and 21E are formed on terminals 40A, 40B, 41A, and 41B and the conductive wire 20B by the inkjet sub-process.

As shown in FIG. 2B, an insulation sub-pattern 12 having five via holes V1 is formed on the insulation sub-pattern 11 by the inkjet sub-process. The respective via holes V1 correspond to respective conductive posts 21A, 21B, 21C, 21D, and 21E. That is, the respective conductive posts 21A, 21B, 21C, 21D, and 21E pass the insulation sub-pattern 12 through the respective via holes V1. As described in the first and second exemplary examples, any one of the inkjet sub-process of forming the conductive posts 21A, 21B, 21C, 21D, and 21E and the inkjet sub-process of forming the insulation sub-pattern 12 may be performed first.

Next, as shown in FIG. 2C, conductive patterns 23A and 23B are formed on the insulation sub-pattern 12 by the inkjet sub-process. The thicknesses of the conductive patterns 23A and 23B are determined such that the upper surfaces of the conductive pattern 23A and 23B are at the same level as the upper surface of the electrode 22A. In FIG. 2C, the conductive pattern 23A is connected to the terminal 40A through the conductive post 21A. The conductive pattern 23B is connected to the terminals 40B and 41A through the conductive posts 21B and 21C.

As shown in FIG. 2C, the conductive posts 23C and 23D are formed on the conductive posts 21D and 21E by the inkjet sub-process. In the present embodiment, the conductive posts 23C and 23D are formed such that the conductive posts 23C and 23D are equal in thickness (i.e., height) to the conductive patterns 23A and 23B.

As shown in FIG. 2D, the insulation sub-pattern 13 is formed on the insulation sub-pattern 12 by the inkjet sub-process. The insulation sub-pattern 13 is formed to surround sides of the conductive patterns 23A and 23B, sides of the conductive post 23C, a side of the electrode 22A of a capacitor, and sides of the conductive post 23D. A sum of the thickness of the insulation sub-pattern 13, the thickness of, the insulation sub-pattern 12, and the thickness of the insulation sub-pattern 11 is substantially equal to the thickness of the capacitor 42 serving as the electronic component. Accordingly, the three stacked insulation sub-patterns 11, 12, and 13 are used to fill a step generated due to the thickness of the capacitor 12. In the present embodiment, the three insulation sub-patterns 11, 12, and 13 are also referred to as an ‘insulation pattern P2.’

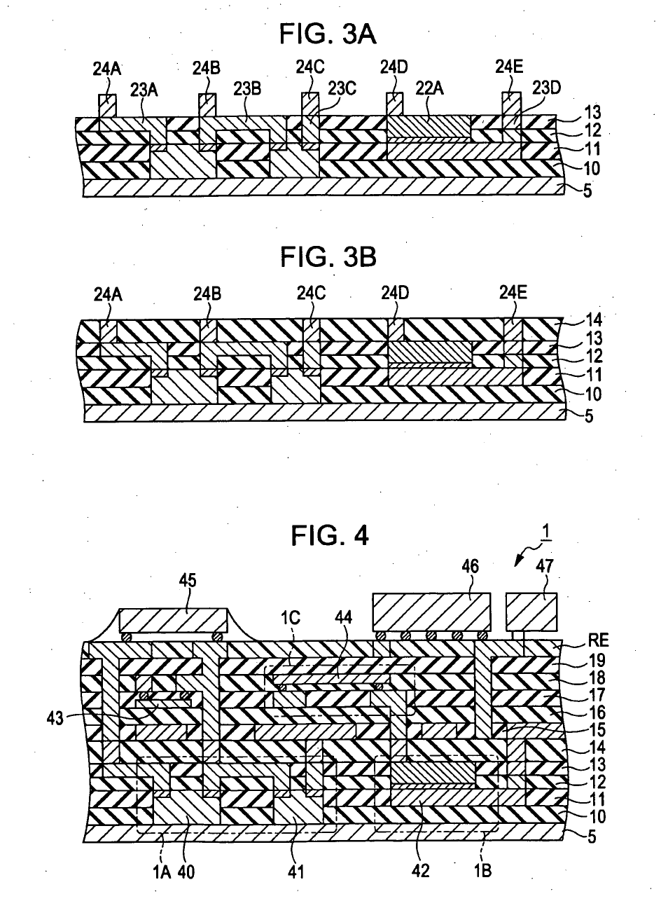

Next, as shown in FIG. 3A, the conductive posts 24A, 24B, 24C, 24D, and 24E are formed on the conductive patterns 23A and 23B, the conductive post 23C, the electrode 22A, and the conductive post 23D, respectively, by the inkjet sub-process. The conductive posts 24A, 24B, 24C, 24D, and 24E have sustantially the same height.

As shown in FIG. 3B, the insulation sub-pattern 14 is formed on the insulation sub-pattern 13 by the inkjet sub-process. The insulation sub-pattern 14 is formed to surround sides of the conductive posts 24A, 24B, 24C, 24D, and 24E. In the present embodiment, the insulation sub-pattern 14 is substantially equal in thickness (or height) to the conductive posts 24A, 24B, 24C, 24D, and 24E. The upper surfaces of the conductive posts 24A, 24B, 24C, 24D, and 24E are exposed on the surface of the insulation sub-pattern 14 such that it is connected to another conductive pattern or conductive post which will be subsequently formed.

The thickness of the insulation sub-pattern 14 may be thinner than the thickness (i.e., height) of the conductive posts 24A, 24B, 24C, 24D, and 24E. When the insulation sub-pattern 14 is smaller in thickness than the conductive posts 24A, 24B, 24C, 24D, and 24E, edges of the conductive posts 24A, 24B, 24C, 24D, and 24E are projected from the surface of the insulation sub-pattern 14. In this case, the conductive posts 24A, 24B, 24C, 24D, and 24E are securely connected to a conductive pattern which will be subsequently provided on the insulation sub-pattern 14.

Subsequently, the above-mentioned process is performed repeatedly and the multi-layered substrate 1 shown in FIG. 4 is manufactured.

In the multi-layered substrate 1 of FIG. 4, the insulation sub-patterns 15, 16, 17, 18, and 19 and a resist layer RE are stacked sequentially on the insulation sub-pattern 14 in this order. An LSI bare chip 43 serving as an electronic component is embedded in the multi-layered substrate 1 by the insulation sub-patterns 17 and 18. In addition, an LSI bare chip 44 serving as an electronic component is embedded in the multi-layered substrate 1 by the insulation sub-pattern 18. An LSI bare chip 45 serving as an electronic component, an LSI package 46, and a connector 47 are provided on the resist layer RE.

The insulation sub-patterns 10, 11, 12, 13, 14, 15, 16, 17, 18, and 19 and the resist layer RE individually or in combination with other insulation sub-patterns are used to fill a step formed due to the conductive pattern, conductive post, or electronic component.

Thus, a plurality of layers provided on the multi-layered substrate 1 can be formed one-by-one by the inkjet process. Accordingly, if there is a defect in the pattern, it can be corrected by the inkjet sub-process before the following layers are stacked, thus improving the yield of the multi-layered substrate 1.

Hereinafter, a method of manufacturing the multi-layered substrate 1 will be described in detail by placing priority to each of the three sections 1A, 1B, and 1C. Section 1A is a part in which the electronic components 40 and 41 are formed. Section 1B is a part in which a capacitor 42 serving as an electronic component is formed. Section 1C is a part in which an LSI bare chip 44 serving as an electronic component is formed.

### FIRST EXEMPLARY EXAMPLE

1. Process of Making a Lyophilic Surface

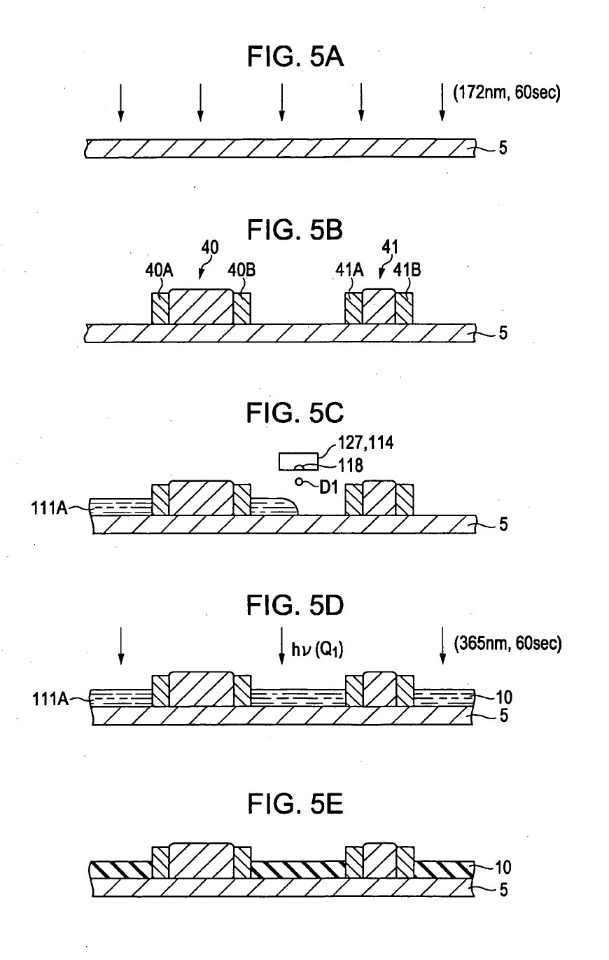

As shown in FIG. 5A, the surface of the base layer 5 is equally lyophilic. In specific detail, light having a wavelength of an ultraviolet range is irradiated for a predetermined time. In the exemplary example, light having a wavelength of 172 nm is irradiated on the base layer 5 for about 60 seconds. As a result, the surface of the base layer 5 is equally lyophilic with respect to the insulation material 111A. The surface of the base layer 5 is substantially flat.

Next, as shown in FIG. 5B, the electronic components 40 and 41 are arranged in respective positions on the base layer 5. The electronic component 40 has terminals 40A and 40B. The electronic component 41 has terminals 41A and 41B. In the embodiment, when the electronic components 40 and 41 are provided on the base layer 5, the electronic components 40 and 41 are provided such that the terminals 40A, 40B, 41A, and 41B are provided to face upwards. As described above, the electronic components 40 and 41 are a surface-mounted resistor and a chip inductor, respectively.

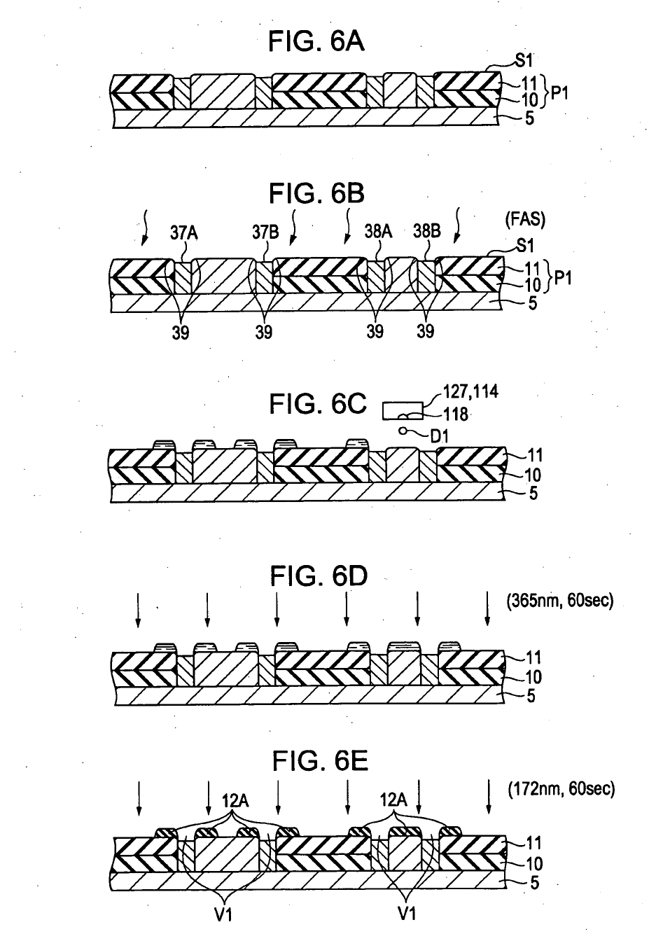

When the electronic components 40 and 41 are provided on the base layer 5, a step is formed on the base layer 5 due to the thickness of the electronic components 40 and 41. As shown in FIGS. 5C to 6A, an insulation pattern P1 is formed on the base layer 5 by the inkjet process. Upon forming the insulation pattern P1, the thickness of the insulation pattern P1 is set such that the insulation pattern P1 is substanitally equal in thickness to the electronic components 40 and 41. In addition, the insulation pattern P1 is formed such that the insulation pattern P1 surrounds the sides of the electronic components 40 and 41. As a result, the insulation pattern P1 is used to fill a step generated due to the thickness of the electronic components 40 and 41. In addition, the side of the insulation pattern P1 and the side of the electronic components 40 and 41 preferably come in contact with each other. As described above, the electronic components 40 and 41 are substantially equal in height to each other.

As described above, the insulation pattern P1 consists of two insulation sub-patterns 10 and 11 which are stacked. The inkjet sub-process of forming each of the insulation sub-patterns 10 and 11 will be described in detail.

2. Insulation Sub-Pattern 10

As shown in FIGS. 5C to 5E, the insulation sub-pattern 10 is formed on the base layer 5 by the inkjet sub-process. The thickness of the insulation sub-pattern 10 is almost half the height of the electronic components 40 and 41. The insulation sub-pattern 10 is formed to cover a part of the base layer 5 where the electronic components 40 and 41 are not provided.

In specific detail, as shown in FIG. 5C, a position of a nozzle 118 relative to the base layer 5 is changed in two dimensions by using the liquid droplet ejection apparatus 100 of FIG. 16. When the nozzle 118 is positioned at a region corresponding to a part on which the base layer 5 is exposed, liquid droplets D1 of the insulation material 111A are ejected on the base layer 5. As shown in FIG. 5A, since the base layer 5 is lyophilic with respect to the insulation material 11A, the liquid droplets D1 placed on the base layer 5 are wet and likely to be diffused on the base layer 5. As a result, the liquid droplets D1 are wet and diffused on the base layer 5, thereby obtaining a material pattern of the insulation material 111A.

Next, as described in FIG. 5D, the prepared material pattern is activated. In specific detail, light having a wavelength of 365 nm is irradiated on the material pattern for about 60 seconds. As a result, a polymerization process of a monomer in the material pattern is performed, thereby obtaining the insulation sub-pattern 10 shown in FIG. 5E.

Here, in addition to the process of irradiating light, the activation process of FIG. 5D may include a process of heating the material pattern by adding heat capacity Q1 so that the polymerization process of the monomer is promoted by the heat. It should be understood that the activation process may not necessarily include the process of irradiating light depending on the insulation material 111A. When the insulation material 111A is an aqueous material of a polymer which will become the insulation sub-pattern 10 afterwards, the activation process may include a process of vaporizing a solvent from the material pattern. In specific detail, the activation process in this case is a process of heating the material pattern using a heater or infrared light.

3. Insulation Sub-Pattern 11

Next, as shown in FIG. 6A, the insulation sub-pattern 11 is formed on the insulation sub-pattern 10 by the inkjet sub-process. The inkjet sub-process of forming the insulation sub-pattern 11 is basically the same as the process of forming the insulation sub-pattern 10 as shown in FIGS. 5C to 5E, and a detailed description thereof will thus be omitted.

The thickness of the insulation sub-pattern 11 is set such that the sum of the thickness of the insulation sub-pattern 10 and the thickness of the insulation sub-pattern 11 is substantially equal to the thickness of the electronic components 40 and 41. As a result, the insulation sub-patterns 10 and 11 serve to eliminate a step formed between the surface of the base layer-5 and the electronic components 40 and 41.

As described above, the two stacked insulation sub-patterns 10 and 11 constitute the insulation pattern P1. When the electronic component 40 (41) has a relatively small thickness, the insulation pattern P1 may be formed of a layer of insulation sub-pattern. When the electronic component 40 (41), has a relatively large thickness, the insulation pattern P1 may be formed of three or more layers of insulation sub-pattern.

The surface of the insulation pattern P1 is formed to be at the same level as the surface of the electronic components 40 and 41, thereby obtaining almost a continuous or flat surface S1. When the surface S1 is substantially flat, the surface S1 may be inclined with respect to the base layer 5.

4. Via Hole V1

Next, a via hole V1 is provided on each of the terminals 40A, 40B, 41A, and 41B. The outer shape of the via hole V1 is formed on the edge by the insulation sub-pattern 12 provided on the surface S. As described below, in the embodiment, the insulation sub-pattern 12 is formed on the surface S1 by the inkjet sub-process.

As shown in FIG. 6B, the surface S1 is lyophobic. In the embodiment, a fluoroalkyl silane (FAS) film is formed on the surface S1. In specific detail, a solution of a compound (i.e., FAS) and the base layer 5 are put in the same sealed vessel for two or three days at room temperature. As a result, a self-organized film (i.e., FAS film) composed of an organic molecule film is formed on the surface S1.

In the embodiment, post-forming regions 37A and 37B are formed on the terminals 40A and 40B, respectively. Similarly, post-forming regions 38A and 38B are formed on the terminals 41A and 41B, respectively. The post-forming regions 37A, 37B, 38A, and 38B are positions where conductive posts are provided. A region surrounding each of the post-forming regions 37A, 37B, 38A, and 38B is hereinafter referred to as a ‘base region 39’.

Next, an edge 12A is formed on the four base regions 39 by the inkjet sub-process.

As shown in FIG. 6C, a liquid droplet D1 of the insulation material 111A is ejected on the base region 39. Then, a plurality of liquid droplets D1 is placed, wet, and diffused on each of the four base regions 39. When the placed liquid droplets D1 are diffused, a material pattern is formed on each of the four base regions 39.

Since the four base regions 39 are part of the lyophobic surface S1, the base region 39 becomes lyophobic with respect to the insulation material 111A. That is, the liquid droplets D1 of the insulation material 111A placed on the base region 39 are less diffused. Thus, the four base regions 39 are suitable for taking the via holes V1 by the inkjet sub-process. In addition, in the present embodiment, the lyophobic surface S1 implies a surface of the FAS film covering the surface S1.

Next, as shown in FIG. 6D, four material patterns are cured to form four edges 12A. In specific detail, light having a wavelength in an ultraviolet range is irradiated on the material pattern for about 60 seconds to obtain the edge 12A. In the embodiment, the wavelength of the light irradiated on the material pattern is 365 nm. The inner sides of the four respective edges 12A become the via holes. That is, each of the via holes V1 is formed on each of the four edges 12A.

Next, an inner part 12B surrounding the four edges 12A is formed by the inkjet sub-process.

As shown in FIG. 6E, the surface S1 is made lyophilic after the four edges 12A are formed. In this case, light having a wavelength in an ultraviolet range is uniformly irradiated on the surface S1 for about 60 seconds, such that the FAS film on the surface S1 is removed. After the FAS film is removed from the surface, the above-mentioned light is further irradiated on the surface S1, such that the surface S1 is lyophilic with respect to the insulation material 111A. In the embodiment, the wavelength in the ultraviolet range is 172 nm. An index representing a degree of lyophilicity is a ‘contact angle’. In the embodiment, when the liquid droplet D1 of the insulation material 111A contacts the lyophilized surface S1, the contact angle between the liquid droplet D1 and the surface S1 is 20° or less.

The liquid droplet D1 of the insulation material 111A is ejected on the surface S1 to form a material pattern of the insulation material 111A. As described above, the surface S1 is lyophilic with respect to the insulation material 111A due to the above-mentioned process of making the surface S1 lyophilic. As a result, insulation material 111A on the surface S1 may be wet and diffused in a wide range.

Even though not shown, an inner part 12B is formed from the cured material pattern. In specific detail, light having a wavelength in an ultraviolet range is irradiated on the material pattern for about 60 seconds to obtain the inner part 12B. In the embodiment, the wavelength of the light to be irradiated on the material pattern is 365 nm.

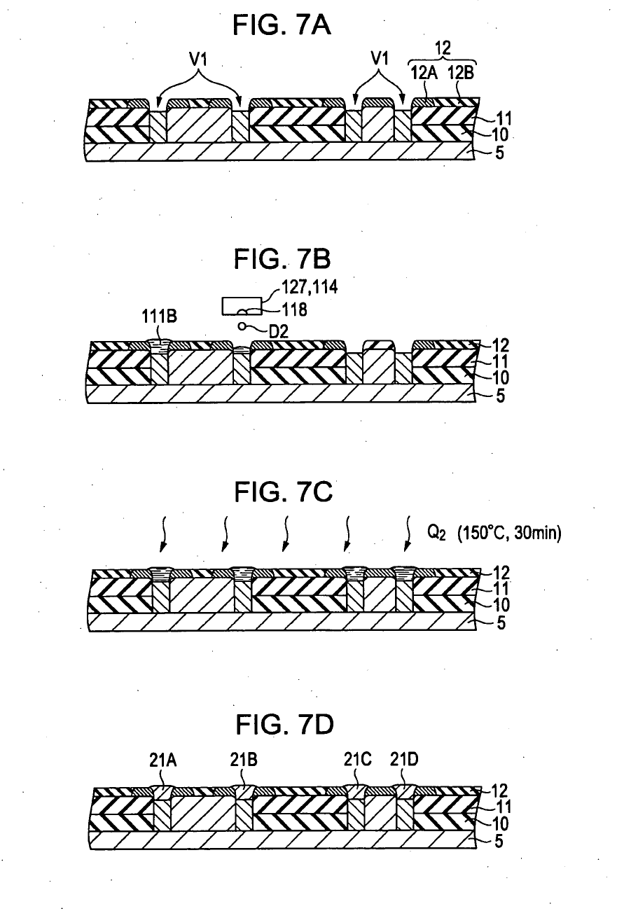

From the above-mentioned processes, as shown in FIG. 7A, the insulation sub-pattern 12 having four edges 12A and one inner part 12B can be obtained.

5. Conductive Posts 21A, 21B, 21C, and 21D

After forming the four via holes V1, the conductive posts 21A, 21B, 21C, and 21D are provided in the four via holes V1 by the inkjet sub-process.

As shown in FIG. 7B, liquid droplets D2 of the conductive material 111B are ejected into each of the via holes V1. The liquid droplets D2 are placed so as to be wet and diffused on the surfaces of the terminals 40A, 40B, 41A, and 41B that form a bottom portion of each of the via holes V1. The liquid droplets D2 of the conductive material 111B are continuously ejected until the inner part of each of the via holes V1 is filled with the conductive material 111B.

As shown in FIG. 7C, heat capacity Q2 is applied on the conductive material 111B to activate the conductive material 111B. In this case, a solvent in the conductive material 111B is vaporized and, at the same time, conductive particles in the conductive material 111B are sintered or melted to be fixed. As a result, as shown in FIG. 7D, the conductive posts 21A, 21B, 21C, and 21D formed through the insulation sub-pattern 12 can be obtained on each of the four via holes V1.

6. Conductive Patterns 23A and 23B

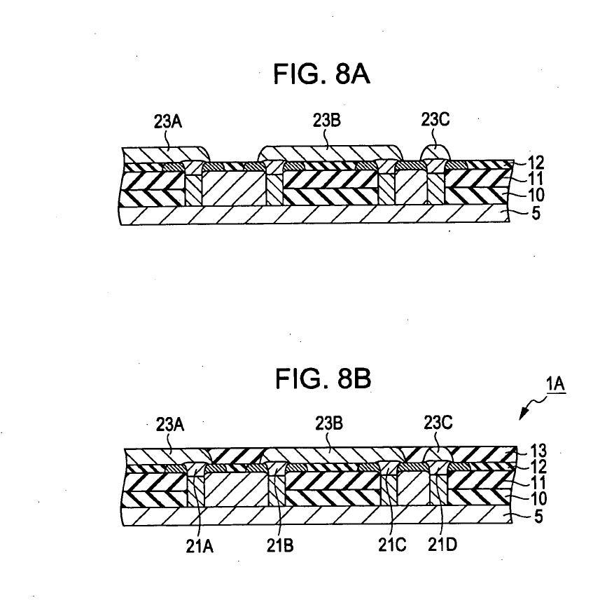

Next, as shown in FIG. 8A, the conductive patterns 23A and 23B are formed on the insulation sub-pattern 12 by the inkjet sub-process. In addition, the conductive post 23C is formed on the conductive post 21D by the inkjet sub-process. The inkjet sub-process of forming the conductive post 23C is basically the same as that of forming the conductive post of the second exemplary example.

The conductive pattern 23A is conductively connected to the conductive post 21A exposed on the insulation sub-pattern 12. Since the conductive post 21A and the terminal 40A are conductively connected to each other, the conductive pattern 23A is conductively connected to the electronic component 40 through the conductive post 21A. Similarly, the conductive pattern 23B is conductively connected to two conductive posts 21B and 21C exposed on the insulation sub-pattern 12. The conductive post 21B and the terminal 40B are conductively connected to each other, and the conductive post 21C and the terminal 41A are conductively connected to each other. Accordingly, the conductive pattern 23B is used to connect in series the electronic component 40 and the electronic component 41. The conductive post 23C is conductively connected to the conductive post 21D exposed in the insulation sub-pattern 12. Since the conductive post 21D and the terminal 41B are conductively connected to each other, the conductive post 23C is conductively connected to the electronic component 41 through the conductive post 21D.

7. Insulation Pattern 13

Next, as shown in FIG. 8B, the insulation sub-pattern 13 is formed on the insulation sub-pattern 12 by the inkjet sub-process. The insulation sub-pattern 13 is formed to surround sides of the conductive patterns 23A and 23B and a side of the conductive post 23C. The insulation sub-pattern 13 is substantially equal in thickness (or height) to the conductive patterns 23A and 23B and the conductive post 23C. Thus, the surface of the insulation sub-pattern 13, the surface of the conductive patterns 23A and 23B, and the surface of the conductive post 23C form substantially a single flat surface. In addition, the inkjet sub-process of forming the insulation sub-pattern 13 is the same as that of forming each of the insulation sub-patterns 10 and 11, and a detailed description will thus be omitted.

From the above-mentioned processes, the section 1A shown in FIG. 4 can be obtained. According to the embodiment, since the multi-layered substrate is formed by the inkjet process, it is easy to find a defect in a pattern before stacking the respective layers and to correct the defect in the pattern.

### SECOND EXEMPLARY EXAMPLE

The exemplary example is basically equal to the first exemplary example except for the inkjet sub-process of forming the conductive posts 21A, 21B, 21C, and 21D and the inkjet sub-process of forming the insulation sub-pattern 12.

As described in the first exemplary example, two electronic components 40 and 41 are provided on a predetermined position of the base layer 5. Next, an insulation pattern P1 is formed by the inkjet process. As described above, the insulation pattern P1 consists of stacked insulation sub-patterns 10 and 11, and is used to fill a step generated due to the thickness of the base layer 5. In addition, the surface of the insulation pattern P1 and the surfaces of the electronic components 40 and 41 form a single ‘surface S1’.

1. Conductive Posts 21A, 21B, 21C, and 21D

In the embodiment, the conductive posts 21A, 21B, 21C, and 21D are formed by the inkjet sub-process prior to forming the insulation sub-pattern 12. A detailed description thereof will be given below.

The liquid droplets D2 of the conductive material 111B are ejected on the terminals 40A, 40B, 41A, and 41B and a material pattern is provided. The material pattern is temporarily dried, and a sub post is formed on each of the terminals 40A, 40B, 41A, and 41B. The temporary drying process is performed such that at least the surface of the material pattern is dried. More specifically, dry air may be sprayed or infrared light may be irradiated for the temporary drying process.

The ejection of the liquid droplets D2 and the temporary drying process are repeatedly performed, and four sub posts are stacked on each of the terminals 40A, 40B, 41A, and 41B.

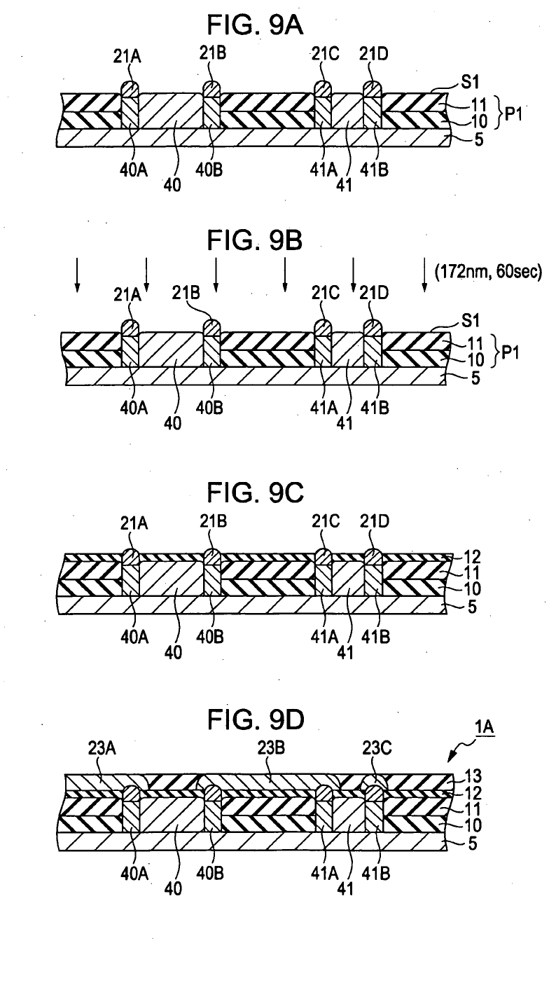

Next, the four sub posts stacked on the terminals 40A, 40B, 41A, and 41B are activated. In the embodiment, the base layer 5 is heated on a hot plate at a temperature of 150° C. for 30 minutes. In this case, a solvent remaining in each of the sub posts is vaporized and, at the same time, conductive particles in each of the sub posts are sintered or melted to be fixed. As a result, as shown in FIG. 9A, the conductive posts 21A, 21B, 21C, and 21D can be obtained on the terminals 40A, 40B, 41B, and 41B.

2. Insulation Pattern 12

Next, the insulation pattern 12 is provided on the surface S1 by the inkjet sub-process. A detailed description thereof will be given below.

As shown in FIG. 9B, the surface S1 is made lyophilic. In the embodiment, light having a wavelength in an ultraviolet range is irradiated on the surface S1. In specific detail, light having a wavelength of about 172 nm is irradiated on the surface S1 for about 60 seconds.

Next, even though not shown, the liquid droplets D1 of the insulation material 111A are ejected, and a material pattern of the insulation material 111A is provided on the surface S1. The material pattern is preferably provided such that the material pattern of the insulation material 111A and a side of the conductive posts 21A, 21B, 21C, and 21D do not contact each other. At this time, preferably, there is a gap between the material pattern of the insulation material 111A and the conductive posts 21A, 21B, 21C, and 21D.

Next, although not shown, the surface S1 exposed at a gap between the material pattern of the insulation material 111A and the conductive posts 21A, 21B, 21C, and 21D is made to be lyophilic one more time. In specific detail, light having a wavelength of 172 nm is irradiated on the surface S1. As a result, the lyophilicity of the surface S1 with respect to the insulation material 111A is increased. Further, the material pattern of the insulation material 111A is wet and diffused until it contacts the sides of the conductive posts 21A, 21B, 21C, and 21D. That is, the gaps between the material pattern of the insulation material 11A and the conductive posts 21A, 21B, 21C, and 21D are filled with the material pattern by performing the process of making the surface lyophilic again.

In the embodiment, by the second process of making the surface lyophilic, the material pattern of the insulation material 111A is further wet and diffused. By doing so, it is possible to securely come in contact with the material pattern of the insulation material 111A and the sides of the conductive posts 21A, 21B, 21C, and 21D with each other and, at the same time, to securely expose the upper sides of the conductive posts 21A, 21B, 21C, and 21D from the material pattern of the insulation material 111A. As a result, the conductive posts 21A, 21B, 21C, and 21D pass through the insulation sub-pattern 12 reliably.

The material pattern of the insulation material 111A is then activated. In specific detail, light having a wavelength in an ultraviolet range is irradiated on the insulation material pattern to cure the insulation material pattern. Then, as a polymerization process of a monomer in the material pattern of the insulation material 111A is performed, the insulation sub-pattern 12 can be obtained from the insulation pattern of the insulation material 111A as shown in FIG. 9C.

3. Conductive Patterns 23A and 23B

Next, as described in the first exemplary example, the conductive patterns 23A and 23B are formed on the insulation sub-pattern 12 by the inkjet sub-process. The conductive post 23C is formed on the conductive post 21D by the inkjet sub-process. As described in the first exemplary example, the insulation pattern 13 is formed on the insulation sub-pattern 12 by the inkjet sub-process.

When the above-mentioned process is performed, as described in FIG. 9D, the section 1A of FIG. 4 can be obtained.

### MODIFIED EXAMPLES OF FIRST AND SECOND EXEMPLARY EXAMPLES

(1) In the first and second exemplary examples, the conductive post 21A and conductive pattern 23A that join with each other are individually formed by the inkjet sub-process. However, when the depth of the via hole V1 is relatively small, the conductive pattern 23A may be directly connected to the terminal 40A without forming the conductive post 21A. In this case, as described in the first exemplary example, the insulation sub-pattern 12, in which the via hole is formed on an edge of the terminal 40A, is formed on the insulation sub-pattern 11 by the inkjet sub-process. Subsequently, the conductive pattern 23A is formed on the terminal 40A and the insulation sub-pattern 12 by the inkjet sub-process.

(2) In the first and second exemplary examples, the conductive posts 21A, 21B, 21C, and 21D are formed on the terminals 40A, 40B, 41A, and 41B by the inkjet sub-process. When each of the terminals 40A, 40B, 41A, and 41B is formed in a bump-shape, the conductive posts 21A, 21B, 21C, and 21D may not be formed. In this case, the electronic components 40 and 41 are provided on the base layer 5 so that bumps of the electronic components 40 and 41 can face upward. The insulation pattern P1 is formed on the base layer 5 by the inkjet process. The insulation pattern P1 is formed to cover the electronic components 40 and 41 except for the bumps. The insulation sub-pattern 12 is formed on the insulation pattern P1 by the inkjet sub-process. The insulation sub-pattern 12 is formed to surround the sides of the bump. Subsequently, if necessary, the conductive pattern 23A connected to the bump may be formed on the insulation sub-pattern 12 by the inkjet sub-process.

### THIRD EXEMPLARY EXAMPLE

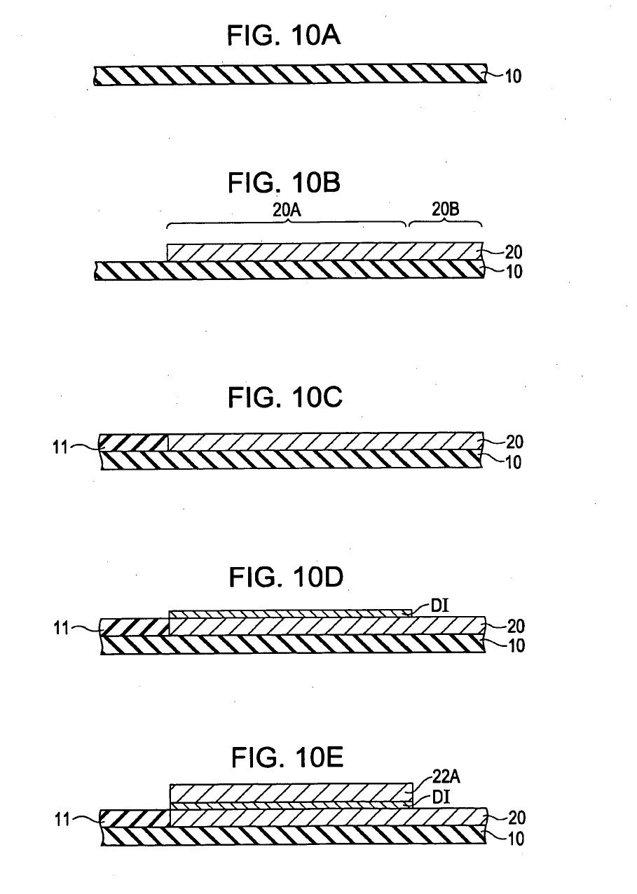

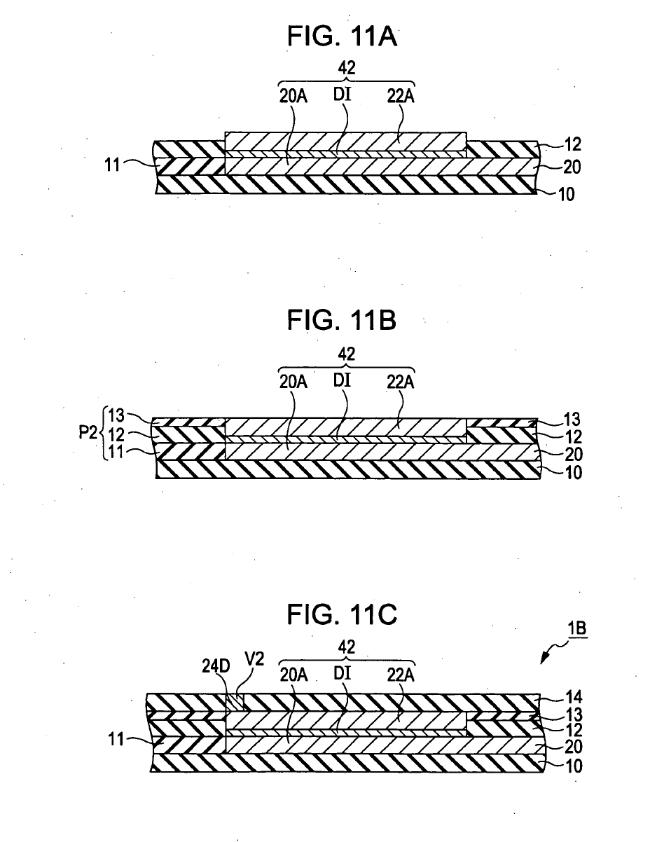

A process of forming the section 1B of FIG. 4 will be described with reference to FIGS. 10 and 11. The same elements as those of the first exemplary example are denoted as the same reference numerals and a detailed description thereof will thus be omitted. In the present exemplary example, as shown in FIG. 10A, the insulation sub-pattern 10 is already provided.

As shown in FIG. 10B, the conductive pattern 20 is formed on the insulation sub-pattern 10 by the inkjet sub-process. The conductive pattern 20 includes the electrode 20A and the conductive wire 20B that are connected to each other. As shown in FIG. 10C, the insulation sub-pattern 11 is formed on the insulation sub-pattern 10 by the inkjet sub-process. The insulation sub-pattern 11 is formed to surround the sides of the conductive pattern 20. In the embodiment, the insulation sub-pattern 11 and the conductive pattern 20 are equal in thickness to each other.

Next, as shown in FIG. 10D, a dielectric layer DI is formed on the electrode 20A by the inkjet sub-process. Subsequently, as shown in FIG. 10E, the electrode 22A is formed on the dielectric layer DI by the inkjet sub-process. As shown in FIGS. 11A and 11B, the insulation sub-pattern 12 and the insulation sub-pattern 13 are formed on the insulation sub-pattern 11 and the conductive pattern 20 by the inkjet sub-process. In the present embodiment, the insulation sub-patterns 12 and 13 are formed to surround the side of the electrode 22A. In addition, the insulation sub-patterns are formed such that an upper surface of the insulation sub-pattern 13 is formed to have the same level as an upper surface of the electrode 22A. The insulation sub-patterns 12 and 13 may be formed of a single layer.

In the exemplary example, the sum of the thickness of the insulation sub-pattern 11, the thickness of the insulation sub-pattern 12, and the insulation sub-pattern 13 is equal to the thickness of the capacitor 42. Accordingly, the three stacked insulation sub-patterns 11, 12, and 13 are used to fill a step generated due to the thickness of the capacitor 42. In addition, the upper surface of the insulation sub-pattern 13 located at the uppermost part and the upper surface of the capacitor 42 form almost a single, flat surface. In the embodiment, the three insulation sub-patterns 11, 12, and 13 are collectively referred to as an ‘insulation pattern P2.’

As shown in FIG. 11C, the conductive post 24D is formed on the electrode 22A by the inkjet sub-process. The insulation sub-pattern 14 is formed on the insulation sub-pattern 13 and the electrode 22A by the inkjet sub-process. As described in the first and second exemplary examples, any one of the inkjet sub-process of forming the conductive post 24D and the inkjet sub-process of forming the insulation sub-pattern 14 may be performed first. The via hole V2 is formed on the electrode 22A at an edge of the insulation sub-pattern 14. The conductive post 24D passes the insulation sub-pattern 14 through the via hole V2.

The section 1B of FIG. 4 can be obtained by the above-mentioned process.

### FOURTH EXEMPLARY EXAMPLE

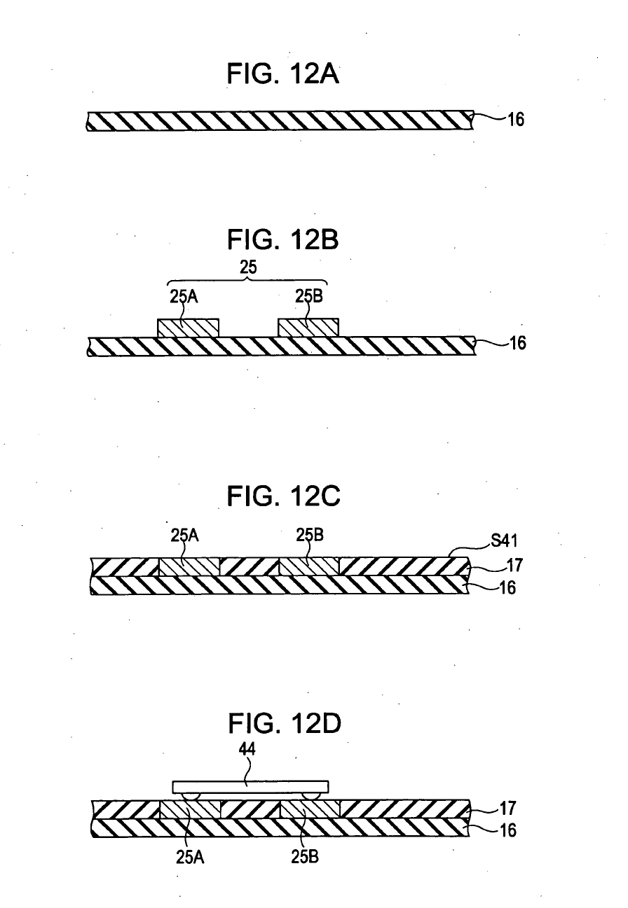

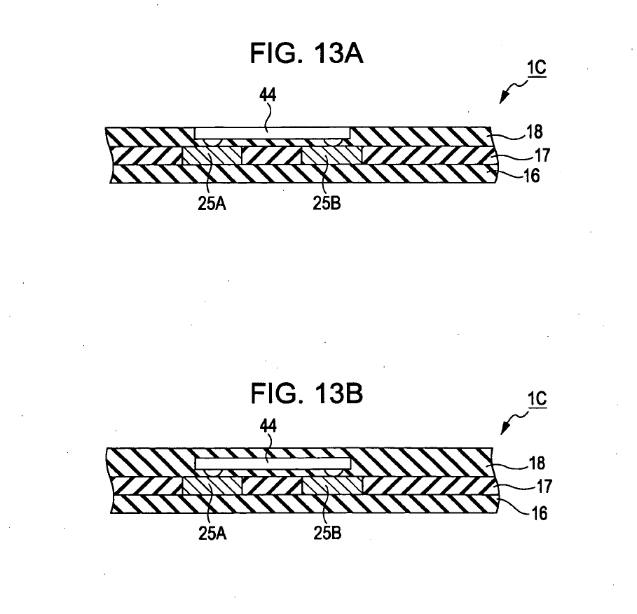

A process of forming the section 1C of FIG. 4 will be described with reference to FIGS. 12 and 13. The same elements as those of the first exemplary example are denoted as the same reference numerals and a detailed description thereof will thus be omitted herein. In the embodiment, as shown in FIG. 12A, the insulation sub-pattern 16 is already provided.

As shown in FIG. 12B, the conductive pattern 25 is formed on the insulation sub-pattern 16 by the inkjet sub-process. The conductive pattern 25 has two lands 25A and 25B that are separated from each other. In the exemplary example, an LSI bare chip 44 is provided on the two lands 25A and 25B.

As shown in FIG. 12C, the insulation sub-pattern 17 is formed on the insulation sub-pattern 16 by the inkjet sub-process. The insulation sub-pattern 17 is formed to surround the sides of the conductive pattern 25. The insulation sub-pattern 17 and the conductive pattern 25 are almost equal in thickness to each other. The surface of the insulation sub-pattern 17 and the surface of the conductive pattern 25 form a single, flat surface S41.

As shown in FIG. 12D, the LSI bare chip is provided on the lands 25A and 25B so that two terminals of the LSI bare chip 44 come in contact with the two lands 25A and 25B. Subsequently, as shown in FIG. 13A, the insulation sub-pattern 18 is formed on the surface S1 by the inkjet sub-process. The insulation sub-pattern 18 is formed to surround the side of the LSI bare chip 44. In addition, the insulation sub-pattern 18 and the LSI bare chip 44 are substantially equal in thickness to each other. Accordingly, the insulation sub-pattern 18 is used to fill a step formed between the LSI bare chip 44 and the insulation sub-pattern 17. The surface of the insulation sub-pattern 18 and the surface of the LSI bare chip form substantially a single, flat surface.

As, described with reference to the insulation sub-patterns 10 and 11 of the first exemplary example, the inkjet sub-process of forming the insulation sub-pattern 18 may include the inkjet sub-process of forming each of the insulation sub-patterns. In addition, as shown in FIG. 13B, when the thickness of the LSI bare chip 44 is relatively small, the insulation sub-pattern 18 may be formed to completely cover the upper surface of the LSI bare chip.

### FIFTH EXEMPLARY EXAMPLE

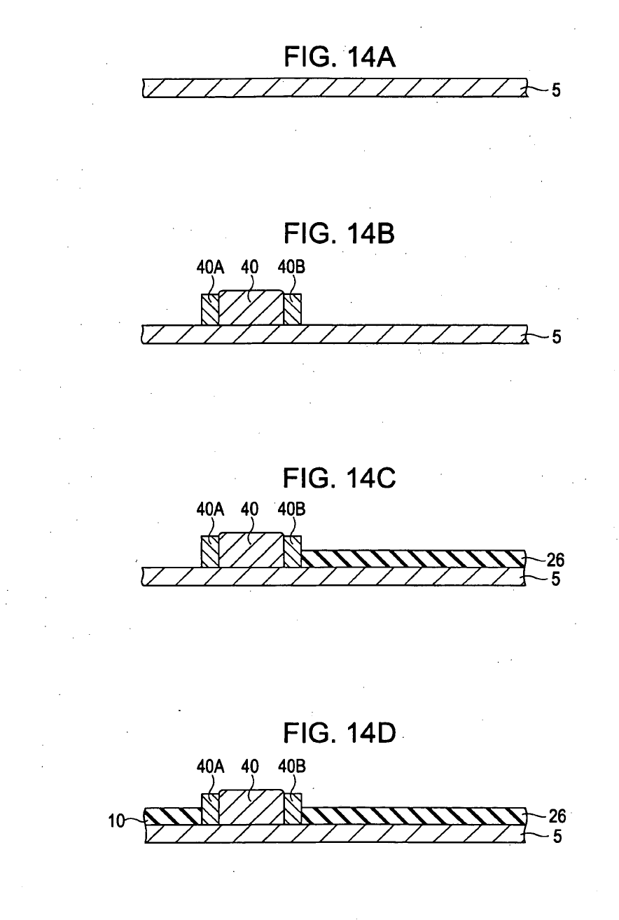

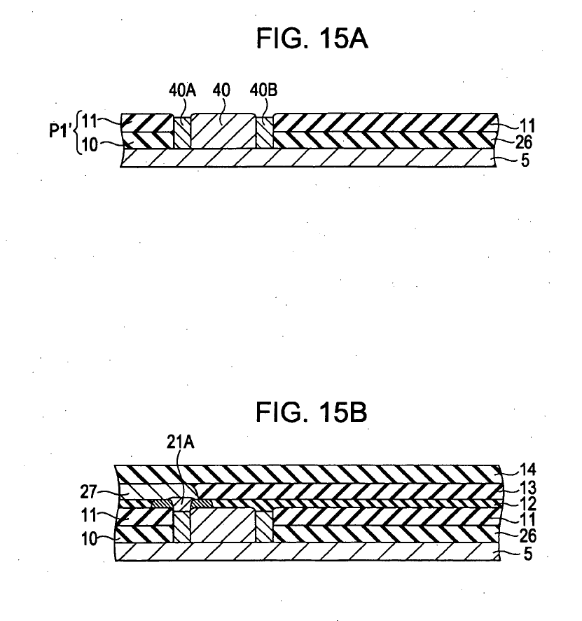

A method of embedding the electronic component 40 in the section 1A of FIG. 4 according to another embodiment will be described with reference to FIGS. 14 and 15.

As shown in FIGS. 14A and 14B, the electronic component 40 is provided at a predetermined position of the base layer 5 using a mounter. The terminals 40A and 40B of the electronic component 40 come in contact with the surface of the base layer 5.

As shown in FIG. 14C, the conductive pattern 26 is formed to come in contact with the terminal 40B of the electronic component 40 on the base layer 5 by the inkjet sub-process. The conductive pattern 26 of the exemplary example is a conductive wire. As shown in FIG. 14D, the insulation sub-pattern 10 is formed on the base layer 5 by the inkjet sub-process. The insulation sub-pattern 10 is formed to surround the sides of the conductive pattern 26. In addition, the insulation sub-pattern 10 and the conductive pattern 26 are almost equal in thickness to each other. Accordingly, the insulation sub-pattern 10 is used to fill a step generated due to the thickness of the conductive pattern 26.

As shown in FIG. 15A, the insulation sub-pattern 11 is formed on the insulation sub-pattern 10 and the conductive pattern 26 by the inkjet sub-process. The thickness of the insulation sub-pattern 11 is set such that the sum of the thickness of the insulation sub-pattern 10 and the thickness of the insulation sub-pattern 11 is substantially equal to the thickness of the electronic component 40. As a result, the insulation sub-patterns 10 and 11 eliminate a step generated due to the thickness of the electronic component 40. In the exemplary example, the two insulation sub-patterns 10 and 11 are also referred to as an ‘insulation pattern P1′’.

When the thickness of the electronic component 40 is relatively small, the insulation pattern P1′ may be formed of a layer of insulation sub-pattern. In addition, when the thickness of the electronic component 40 is relatively larger than, the insulation pattern P1′ may be formed of three or more insulation sub-patterns.

As shown in FIG. 15B, the conductive post 21A contacting the terminal 40A, and the insulation sub-pattern 12 surrounding the sides of the conductive post 21A are formed. The conductive post 21A and the insulation sub-pattern 12 may be formed by the inkjet sub-process, for example, similarly to the conductive post 21A and the insulation sub-pattern 12 of the first exemplary example.

Next, the conductive pattern 27 is formed on the insulation sub-pattern 11 by the inkjet sub-process. The conductive pattern 27 is formed to be connected to the conductive post 21A. Subsequently, the insulation sub-pattern 13 is formed on the insulation sub-pattern 12 by the inkjet sub-process. The insulation sub-pattern 13 is formed to surround the sides of the conductive pattern 27. The insulation sub-pattern 13 and the conductive pattern 27 are substantially equal in thickness to each other. Accordingly, the insulation sub-pattern 13 serves to eliminate a step generated due to the thickness of the conductive pattern 27.

In addition, the insulation sub-pattern 14 is formed on the insulation sub-pattern 13 and the conductive pattern 27 by the inkjet sub-process. As described above, the electronic component 40 can be embedded in the multi-layered substrate 1 in the above-mentioned process.

### SIXTH EXEMPLARY EXAMPLE

A. Structure of Liquid Droplet Ejection Apparatus

The methods of manufacturing the multi-layered substrate in the first to fifth exemplary examples are implemented in a plurality of liquid droplet ejection apparatuses. The number of liquid droplet ejection apparatuses may be equal to the number of the above-mentioned inkjet sub-processes or the number of kinds of the following aqueous materials 111. The structures of the liquid droplet ejection apparatuses are basically the same. Thus, the structure and function of the liquid droplet ejection apparatus 100 shown in FIG. 16 will be described in detail.

The liquid droplet ejection apparatus 100 shown in FIG. 16 is basically an inkjet apparatus. In specific detail, the liquid droplet ejection apparatus 100 includes a tank 101 containing the aqueous material 111, a tube 110, a ground stage GS, an ejection head unit 103, a stage 106, a first position control unit 104, a second position control unit 108, a controller 112, a light irradiation unit 140, and a support unit 104a.

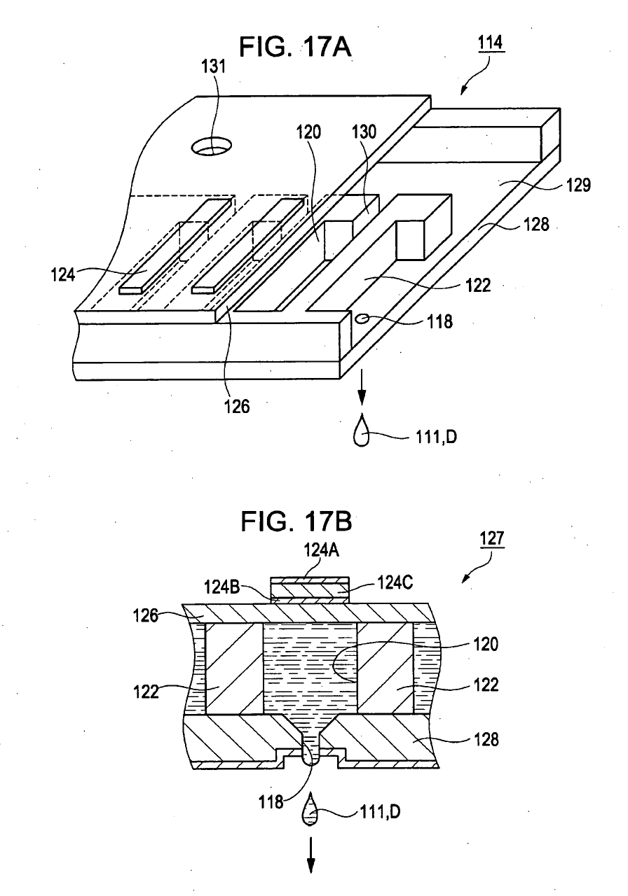

The ejection head unit 103 holds a head 114 (see FIG. 17). The head 114 ejects liquid droplet D of the aqueous material 111 according to a signal from the controller 112. The head 114 in the ejection head unit 103 is connected to the tank 101 through the tube 110. Thus, the aqueous material 111 is supplied from the tank 101 to the head 114.

The stage 106 serves to fix the base layer 5. The stage 106 also serves to fix a position of the base layer 5 by using, absorption force. As described above, the base layer 5 is a flexible substrate made of polyimide and is shaped like a tape. Both end portions of the base layer 5 are fixed to a pair of reels (not shown).

The first position control unit 104 is fixed at a predetermined position from the ground stage GS by the support unit 104a. The first position control unit 104 serves to move the ejection head unit 103 in X-axis direction and Z-axis direction orthogonal to the X-axis direction according to a signal from the controller 112. In addition, the first position control unit 104 serves to rotate the ejection head unit 103 around an axis parallel to the Z-axis. In the exemplary example, the Z-axis direction is a direction parallel to a vertical direction (i.e., in a direction of acceleration of gravity).

The second position control unit 108 moves the stage 106 on the ground stage GS in Y-axis direction according to a signal from the controller 112. The Y-axis direction is a direction orthogonal to both the X-axis and Z-axis directions.

The structure of the first position control unit 104 and second position control unit 108 can be achieved by a well-known X-Y robot using a linear motor or servo motor a detailed description thereof, however, will be omitted. In the present description, the first position control unit 104 and the second position control unit 108 are also referred to as a ‘robot’ or a ‘scanning unit’.

As described above, the ejection head unit 103 is moved in the X-axis direction by the first position control unit 104. The base layer 5 is moved in the Y-axis direction along with the stage 106 by the second position control unit 108. As a result, a position of the head 114 relative to the base layer 5 is changed. In specific detail, the ejection head unit 103, the head 114, or the nozzle 118 (see FIG. 17) relatively moves or scans in the X-axis and Y-axis directions with respect to the base layer 5 while maintaining a predetermined distance to the Z-axis direction. The expression of ‘relative movement’ or ‘relative scans’ implies that at least one of the side on which the aqueous material 111 is ejected and the side (the placed side) on which the ejected aqueous material 111 is placed is moved relatively to the other side.

The controller 112 is configured to receive, from an external information processing apparatus, the ejection data indicating a relative position on which the liquid droplet D of the aqueous material 111 is ejected. The controller 112 stores the ejection data in a storage unit, and controls the first position control unit 104, the second position control unit 108, and the head 114 according to the stored ejection data. The ejection data implies data used for providing the aqueous material 111 on the base layer 5 in a predetermined pattern. In the embodiment, the ejection data is recorded in bitmap form.

The liquid droplet ejection apparatus 100 relatively structured in this manner moves the nozzle 118 (see FIG. 17) of the head 114 to the base layer 5 according to the ejection data, and ejects the aqueous material 111 from the nozzle 118. The relative movement of the head 114 by the liquid droplet ejection apparatus 100 and the ejection of the aqueous material 111 from the head 114 are also denoted as a ‘dispensing scan’ or a ‘ejection scan’.

In the present specification, a part on which the liquid droplet of the aqueous material 111 is placed is also denoted as an ‘ejected part.’ A part on which the liquid droplet is diffused is also denoted as a ‘coated part.’ The ‘ejected part’ and the ‘coated part’ may be formed by performing a surface modification process on a surface of an object such that the aqueous materials 111 indicate a desired contact angle. However, when the surface of the object represents a desired lyophobicity or lyophilicity with respect to the aqueous material 111 without performing the surface modification process (i.e., when the placed aqueous material 111 indicates a desired contact angle on the surface of the object), the surface of the object may be the ‘ejected part’ or the ‘coated part.’

Returning to FIG. 16, the light irradiating unit 140 serves to irradiate ultraviolet light on the aqueous material Ill applied on the base layer 5. The controller 112 controls turning on or off the ultraviolet light irradiation of the light irradiating unit 140.

B. Head

As shown in FIGS. 17A and 17B, the head 114 in the liquid droplet ejection apparatus 100 is an inkjet head having a plurality of nozzles 118. In specific detail, the head 114 includes a vibrating plate 126, a plurality of nozzles 118, a nozzle plate 128 defining an opening of each of the nozzles 118, a liquid collection part 129, a plurality of partitions 122, a plurality of cavities 120, and a plurality of vibrators 124.

The liquid collection part 129 is positioned between the vibrating plate 126 and the nozzle plate 128. The aqueous material 111 supplied from an external tank (not shown) through a hole 131 is filled in the liquid collection part 129. In addition, the plurality of partitions 122 is positioned between the vibrating plate 126 and the nozzle plate 128.

The cavity 120 is surrounded by the vibrating plate 126, nozzle plate 128, and a pair of partitions 122. Since the cavity 120 is provided corresponding to the nozzle 118, the number of cavities 120 is equal to the number of nozzles 118. The aqueous material 111 is supplied from the liquid collection part 129 to the cavity 120 through a supply hole 130 positioned between a pair of partitions 122. In the present embodiment, the nozzle has a diameter of about 27 μm.

A plurality of vibrators 124 are located on the vibrating plate 126 that correspond to each of the cavities 120. Each of the vibrators 124 includes a piezo actuator 124C, and a pair of electrodes 124A and 124B having the piezo actuator 124C interposed therebetween. The controller 112 applies a driving voltage between the electrodes 124A and 124B to eject the liquid droplet D of the aqueous material 111 from a corresponding nozzle 118. The material ejected from the nozzle 118 has a volume ranging from 0 pl to 42 pl (picoliter). In addition, the nozzle 118 is adjusted such that the liquid droplet D of the aqueous material 111 is ejected from the nozzle 118 in the Z-axis direction.

In the present specification, a part that includes one nozzle 118, a cavity 120 corresponding to the nozzle 118, and a vibrator 124 corresponding to the cavity 120 is also denoted as an ‘ejection part’ 127. One head 114 has as many of the ejection parts 127 as the number of nozzles 118. The ejection part 127 may have an electricity-heat conversion element instead of the piezo actuator. That is, the ejection part 127 may have a configuration of ejecting a material by the use of thermal expansion of the material due to the electricity-heat conversion element.

C. Controller

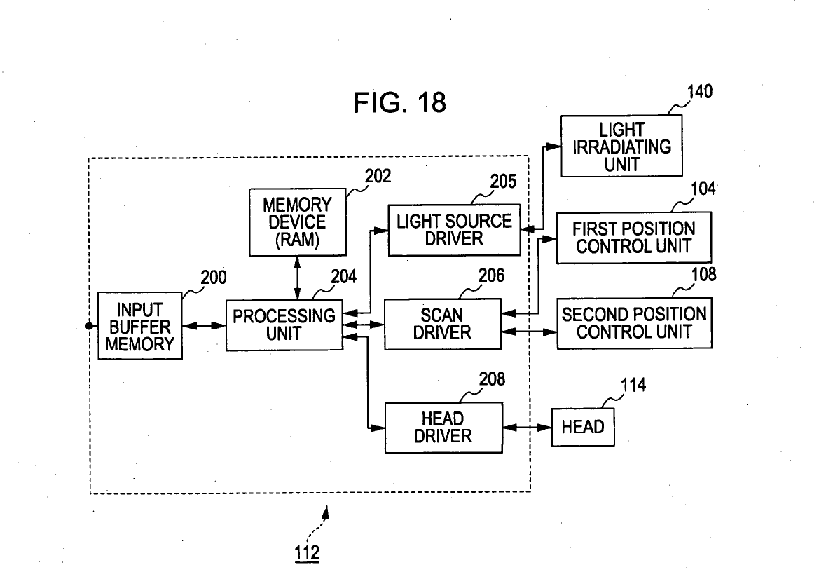

Next, the configuration of the controller 112 will be described. As shown in FIG. 18, the controller 112 includes an input buffer memory 200, a memory unit 202, a processing unit 204, a light source driver 205, a scan driver 206, and a head driver 208. The input buffer memory 200, the processing unit 204, the memory unit 202, the light source driver 205, the scan driver 206, and the head driver 208 are connected to one another by buses so that they can communicate with one another.

The light source driver 205 is connected to a light irradiating unit 140 so that they can communicate with each other. In addition, the scan driver 206 is connected to a first position control unit 104 and a second position control unit 108 so that they can communicate with one another. Similarly, the head driver 208 is connected to a head 114 so that they can communicate with each other.

The input buffer memory 200 receives ejection data for ejecting the liquid droplet D of the aqueous material 111 from an external information processing unit (not shown) located at the outside of the liquid droplet ejection apparatus 100. The input buffer memory 200 supplies the ejection data to the processing unit 204, and the processing unit 204 stores the ejection data in the memory unit 202. In FIG. 18, the memory unit 202 is a RAM.

The processing unit 204 applies data indicating a position of the nozzle 118 relative to a placed part to the scan driver 206 based on the ejection data in the memory unit 202. The scan driver 206 applies the data and a stage driving signal depending on a predetermined ejection cycle to the first and second position control units 104 and 108. As a result, a position of the ejection head unit 103 relative to the ejected subject is changed. On the other hand, the processing unit 204 applies an ejection signal required for ejecting the aqueous material 111 to the head 114 based on the ejection data stored in the memory unit 202. As a result, the liquid droplet b of the aqueous material 111 is ejected from the nozzle 118 corresponding to the head 114.

In addition, the processing unit 204 turns on or off the light irradiating unit 140 based on the ejection data in the memory unit 202. In specific detail, the processing unit 204 supplies a turn-on or turn-off signal to the light source driver 205 so that the light source driver 205 can set the condition of the light irradiating unit 140.

The controller 112 is a computer including CPU, ROM, RAM, and bus. Accordingly, the controller 112 implements the above-mentioned functions by executing software programs stored in the ROM by using the CPU. The controller 112 may be realized with a dedicated circuit (hardware).

D. Aqueous Material

The ‘aqueous material 111’ implies a material having the highest viscosity until it can be ejected as a liquid droplet D from the nozzle 118 of the head 114. The aqueous material 111 may have an aqueous or oily nature. The aqueous material 111 may include a solid substance as long as it is a fluid. Here, the aqueous material 111 preferably has a viscosity in the range of 1 mPa·s to 50 mPa·s. In case of a viscosity having more than 1 mPa·s, the area around the nozzle 118 is seldom contaminated by the aqueous material 111 when the liquid droplet D of the aqueous material 111 is ejected. On the other hand, in the case of when the viscosity is less than 50 mPa·s, the nozzle 118 seldom becomes clogged, such that the liquid droplet D can be smoothly ejected.

The conductive material 111B is a kind of aqueous material 111. The conductive material 111B of the embodiment includes a silver particle having an average diameter of about 10 nm and a dispersion medium. In the conductive material 111B, the silver particles are consistently dispersed in the dispersion medium. The silver particle may be coated with a coating material. The coating material is a compound which is coordinated with a silver atom.

In addition, a particle having an average diameter of about 1 nm to several hundred nm is denoted as a ‘nano particle.’ The conductive material 111B includes a silver nano particle.

The dispersion medium (or solvent) is not particularly restricted as long as it can disperse conductive particles such as silver particles and does not cause aggregation. Examples of the dispersion medium include water; an alcohol such as methanol, ethanol, propanol, or butanol; a hydrocarbon compound such as n-heptane, n-octane, decane, dodecan, tetradecan, toluene, xylene, cymene, durene, indene, dipentene, tetrahydronaphthalene, decahydronaphthalene, or cyclohexylbenzene; an ether compound such as ethylene glycol dimethyl ether, ethylene glycol diethyl ether, ethylene glycol methylethyl ether, diethylene glycol dimethyl ether, diethylene glycol diethyl ether, diethylene glycol methylethyl ether, 1,2-dimetohxyethane, bis(2-methoxyethyl)ether, or p-dioxane; and a polar compound such as propylene carbonate, 7-butyrolacton, N-methyl-2-pyrrolidone, dimethylformamide, dimethylsulfoxide, or cyclohexanone. In terms of dispersibility of the conductive particles, a stability of the dispersion, and easy application the of liquid droplet ejection method, water, alcohol, hydrocarbon compounds, and ether compounds are preferable. Water and hydrocarbon compounds are more preferable.

The above-mentioned insulation material 111A is also a kind of aqueous material 111. The insulation material 111A of the embodiment includes a photosensitive resin material. In specific detail, the insulation material 111A includes photopolymerization initiator, acrylic acid monomer, and/or oligomer.

### FIRST MODIFIED EXAMPLE

The conductive material 111B of the above-mentioned embodiment includes silver nanoparticles. However, nanoparticles of other metals may be used instead of silver nanoparticles. Examples of other metals include gold, platinum, copper, palladium, rhodium, osmium, ruthenium, iridium, iron, tin, zinc, cobalt, nickel, chromium, titanium, tantalum, tungsten, indium, or an alloy formed by combining two or more of the metals. However, since silver is reduced at relatively low temperatures, it is easy to handle. Accordingly, when a liquid droplet ejection apparatus is used, the conductive material 111B including silver nanoparticles is preferably used.

In addition, the conductive material 111B may include an organometallic compound instead of metal nanoparticles. The organometallic compound as used herein is a compound from which a metal is extracted by decomposition under heating. Examples of the organometallic compound include chlorotriethylphosphine gold(I), chlorotrimethylphosphine gold(I), chlorotriphenylphosphine gold(I), silver(I) 2,4-pentanedionate complex, trimethylphosphin(hexafluoroacetylacetonato) silver(I) complex, copper(I) hexafluoropentandionatocyclooctadiene complex, and the like.

Accordingly, the metal contained in the aqueous conductive material 111B may have a particle form, such as nanoparticles, or a compound, such as organometallic compound.

In addition, the conductive material 111B may include a highly polymerized soluble material, such as polyaniline, polythiophene, or polyphenylvinylene.

### SECOND MODIFIED EXAMPLE

As described in the sixth exemplary example, the silver nanoparticles as the conductive material 111B may be coated by a coating material such as organic material. Examples of the coating material include an amine, an alcohol, and a thiol. In specific detail, examples of the coating material include an amine compound such as 2-methylaminoethanol, diethanolamine, diethylmethylamine, 2-dimethylamino ethanol, or methyldiethanolamine, alkylamines, ethylenediamine, alkyl alcohols, ethylene glycol, propylene glycol, alkyl thiol, and ethane dithiol. As a result, the silver nanoparticles coated with the coating material can be dispersed in the dispersion medium consistently.

### Third Modified Example

According to the above-mentioned embodiment, the surface of the base layer 5 and the surfaces of the insulation sub-patterns 10 and 11 are made lyophilic by irradiating light having a wavelength in an ultraviolet range. However, the surfaces can be made lyophilic when they are subjected to an O₂ plasma process in which oxygen is used in an air atmosphere. The O₂ plasma process is a process in which oxygen in a plasma state is radiated onto a surface of an object from a plasma discharge electrode (not shown). The O₂ plasma process is performed under the following conditions: a plasma power in the range of 50 to 1000 W, the volume of flowing oxygen gas in the range of 50 to 100 mL/min, a moving speed of a surface of an object relative to a plasma discharge electrode in the range of 0.5 to 10 nm/sec, and a temperature of the surface of the object in the range; of 70 to 90° C.

### FOURTH MODIFIED EXAMPLE

In the above-mentioned embodiment, the method of manufacturing a multi-layered substrate is implemented by a plurality of liquid droplet ejection apparatuses. However, the number of liquid droplet ejection apparatuses used in the method of manufacturing the multi-layered substrate may be only one. When the number of the liquid droplet ejection apparatuses is one, different aqueous materials 111 may be ejected from different heads 114 in the one liquid droplet ejection apparatus.

### FIFTH MODIFIED EXAMPLE

In the above-mentioned exemplary example, the insulation material 111A includes a photopolymerization initiator, an acrylic acid monomer, and/or an oligomer. However, instead of the acrylic acid monomer and/or oligomer, the insulation material 111A may include a photopolymerization initiator, and a monomer and/or oligomer having a polymerizable functional group such as vinyl or epoxy.

In addition, the insulation material 111A may be an organic solution in which a monomer having a photo functional group is dissolved. A photo-curable imide monomer may be used as a monomer having the photo functional group.

When the monomer, as a material of a resin, has fluidity that is suitable to be ejected from the nozzle 118, the monomer (i.e., monomer solution) may be used as the insulation material 111A instead of an organic solution having the monomer dissolved therein. When the insulation material 111A is used, it is possible to form an insulation pattern or insulation sub-pattern according to the invention.

In addition, the insulation material 111A may be an organic solution in which a polymer as a resin is dissolved. In this case, a toluene may be used as a solvent in the insulation material 111A.

1. A method of manufacturing a multi-layered substrate, comprising:
providing an electronic component on a surface of a substrate so that a terminal of the electronic component faces upward; and
providing a first insulation pattern on the surface so as to fill a step generated due to the thickness of an electronic component.

2. The method of manufacturing a multi-layered substrate according to claim 1, further comprising:
providing a second insulation pattern on the first insulation pattern to form a via hole on an edge of the terminal; and
providing a conductive post in the via hole.

3. The method of manufacturing a multi-layered substrate according to claim 1, further comprising:
providing a conductive post on the terminal; and
providing a second insulation pattern on the first insulation pattern to surround sides of the conductive post.

4. The method of manufacturing a multi-layered substrate according to claim 2, further comprising:
providing a conductive pattern on the second insulation pattern, the conductive pattern being connected to the conductive post; and
providing a third insulation pattern on the second insulation pattern to eliminate a step generated due to a thickness of the conductive pattern.

5. The method of manufacturing a multi-layered substrate according to claim 1, further comprising:
providing a second insulation pattern on the first insulation pattern to form a via hole on an edge of the terminal; and
forming a conductive pattern on the terminal and the second insulation pattern.

6. The method of manufacturing a multi-layered substrate according to claim 5, further comprising:
providing a third insulation pattern on the second insulation pattern to fill a step generated due to a thickness of the conductive pattern.

7. A method of manufacturing a multi-layered substrate comprising:
providing an electronic component on a surface of a substrate so that a bump of the electronic component faces upward;
providing a first insulation pattern on the surface so as to cover a surface the electronic component except for the bump;
providing a second insulation pattern on the first insulation pattern to surround sides of the bump; and
providing a conductive pattern on the second insulation pattern, the conductive pattern being connected to the bump.

8. A method of manufacturing a multi-layered substrate comprising:
providing an electronic component on a conductive pattern so that a terminal of the electronic component comes in contact with a surface of the conductive pattern; and
providing an insulation pattern to fill at least a step generated due to a thickness of the electronic component.

9. A method of manufacturing a multi-layered substrate comprising:
providing a conductive pattern on a surface of a substrate so that the conductive pattern contacts a terminal of an electronic component provided on the surface; and
providing an insulation pattern on the surface to fill at least a step generated due to a thickness of the electronic component.
